(19) United States
(12) Patent Application Publication
(10) Pub. No.: US 2026/0029489 A1
(43) Pub. Date: Jan. 29, 2026

(54) SYSTEM AND METHOD FOR MONITORING MOTOR WINDING DEGRADATION

(71) Applicant: Atlas Copco Airpower, Naamloze Vennootschap, Wilrijk (BE)

(72) Inventors: Hans VANDE SANDE, Wilrijk (BE); Tijs VAN BUGGENHOUT, Wilrijk (BE); Jonas DE KOONING, Wilrijk (BE)

(21) Appl. No.: 19/266,419

(22) Filed: Jul. 11, 2025

Related U.S. Application Data
(60) Provisional application No. 63/676,616, filed on Jul. 29, 2024.

(51) Int. Cl. G01R 31/72; H02P 23/00

(52) U.S. Cl. CPC G01R 31/72; H02P 23/00

(57) ABSTRACT

A system and method are provided for monitoring motor winding degradation of an electric machine having an electric motor driven by a variable speed drive (VSD). Measurements of phase currents and/or phase voltages are detected by sensors of the VSD while simultaneously driving the electric motor. Each measured value is processed using a filtering module to calculate symmetric components. The resulting symmetric component is used to identify the motor winding status of one or more motor windings.

### FIELD OF THE DISCLOSURE

The present disclosure relates to systems, methods, and devices for evaluating insulation conditions of electric machine windings.

### BACKGROUND

A three-phase squirrel cage induction motor is a common electric motor used in commercial applications. A three-phase synchronous motor is less common but still widely used in commercial applications. These motors are used in all types of industries and are implemented in various applications, including compressor, vacuum, fan, and pump systems. Any rotary electric motor, e.g., in an air compressor setting, consists of two main parts: the stationary stator and the rotating rotor. The stator, connected to the three-phase mains supply, produces a rotating magnetic field, which crosses the airgap. In induction motors, this rotating magnetic field induces currents in the squirrel cage on the rotor, which generates magnetic fields. In synchronous motors, a magnetic field is generated on the rotor by permanent magnets or by a three-phase winding connected to a three-phase voltage source via slip rings. The interaction between the stator's and the rotor's magnetic fields generates a torque, causing the rotor shaft to rotate.

While such motors are advantageous due to their simple construction and low cost, failures due to thermal, mechanical, and environmental stresses are inevitable. Many of these failures occur due to the degradation of the motor windings' insulation. For example, thermal stresses caused by increased winding temperature reduce longevity and damage the insulation. Exposure to moisture and particulates also compromises the integrity of the insulation. Mechanical vibrations of motor components may cause even high-quality insulation to deteriorate over time. Because electric motors play a vital role in various industries and commercial applications, unexpected failures in these devices can thus lead to breakdowns, resulting in financial or, in some cases, physical harm.

Generally, fault diagnosis of motors focuses on detecting the failures in the motor components, i.e., the stator, the rotor, and the bearings. Techniques to detect these failures include resistance tests, high-potential tests, surge tests, and partial discharge tests. However, expensive, special equipment is required to perform such tests and said equipment may not assess the condition of the motor winding during normal operation cost-effectively. Alternative techniques require storing the three-phase current values over some prolonged time in memory and applying time-intensive computing techniques, such as Fourier analysis and current signature analysis, to evaluate the quasi-sinusoidal and/or pulse width modulated time waveforms.

As such, there is a need for an improved fault diagnosis system of motor windings to obtain real-time monitoring conditions of the operating electric motor, including the motor winding insulation, to adapt the motor's control better and mitigate dangerous situations.

### SUMMARY

The inventors of the present disclosure have developed a novel technique for using a variable speed drive (VSD) to both drive the motor and monitor the condition of the motor windings. The disclosed technique applies to drives for multi-phase electric motors in general.

The present disclosure relates to systems and methods for monitoring the winding degradation of a multi-phase alternating current electric motor driven by a variable speed drive. By advantageously using sensors of the same variable speed drive responsible for controlling speed and torque of the electric motor, external or remote sensors of supplemental monitoring devices are not required to evaluate the symmetric component values, of whom the negative symmetric component is known to indicate potential motor winding issues. Consequently, the system may be simplified with fewer components, resulting in lower costs.

In an embodiment, the system updates the estimated symmetric components of the three-phase current in real-time, based on combining the previous estimation of the symmetric components with the latest measured three-phase currents using a mathematical model or filtering module. In other words, the system uses the mathematical model or filtering module to instantaneously update the symmetric components based on immediately preceding measured values. The symmetric components of the system, including the positive and negative sequences, are obtained simultaneously using the same algorithm. Moreover, the symmetric components can be computed for the three-phase current and the three-phase voltage to obtain at least four symmetric components, including positive and negative sequences, or six symmetric components to include zero, positive, and negative sequences. Advantageously, particularly in embodiments where a controller is part of a drive, the system can be used to monitor issues that arise in multiple components simultaneously. In a drive, because there is some control of the current, issues or abnormal readings may be observed in the imposed voltage as well; in applications where a motor is directly applied to a strong and stable voltage grid, the voltage is fixed, and issues may not be observed in the symmetric components of the voltage.

The symmetric components are updated for each new incoming measurement of the phase current values. This approach avoids the need to store and process a series of three-phase measurements obtained at relatively high sample rates over an extended period (e.g., 10 periods of a 50 Hz waveform sampled at 2 kHz implies storing 400 numbers per phase and requires applying more advanced and time-intensive signal processing techniques to the entire 400×3 data matrix). Moreover, this approach allows updating the symmetric components at the same rate as the measurements; therefore, faster control actions could be taken. In other words, the system can bypass storing multiple phase current values in a memory to obtain current measurement samples and update the symmetric components in real-time. The calculated symmetric components include a negative sequence current and a positive sequence current.

The system uses a filtering module to obtain the symmetric components. Exemplary filtering modules include extended Kalman filtering (EKF) and/or second-order generalized-integrator (SOGI) filtering. In an exemplary embodiment, the resulting traced features from the filtering module are enhanced by selecting proper parameters that smooth over subsequently obtained values. In embodiments with an extended Kalman filter, the system may provide an estimator for the applied frequency.

Based on the symmetric components, e.g., the negative sequence current, the system can provide a status of the motor winding(s). If the system identifies a significant deviation of the symmetric components (e.g., deviating beyond a predetermined threshold) from the balanced three-phase current system (i.e., three sines having the same frequency and magnitude yet shifted 120° each), then the motor winding status may indicate an insulation issue. For example, a signal may be returned to the variable speed drive in response to the indication of the insulation issue, wherein the deviation exceeds a predetermined threshold value, so that the electric machine may be safely paused or shut down to allow for repairs and maintenance. Additionally, the system may classify levels of deviations as relating to different fault types and/or levels of winding degradation.

This summary is provided to introduce a selection of concepts in a simplified form that are further described below in the Detailed Description. These and other features, aspects, and advantages of the present disclosure will be better understood in the following description, appended claims, and accompanying drawings.

### BRIEF DESCRIPTION OF THE DRAWINGS

To describe how the advantages and features of the systems and methods described herein can be obtained, a more particular description of the embodiments briefly described above will be rendered by reference to specific embodiments thereof, which are illustrated in the appended drawings. Understanding that these drawings depict only typical embodiments of the systems and methods described herein and are not, therefore, considered to be limiting of their scope, certain systems and methods will be described and explained with additional specificity and detail through the use of the accompanying drawings in which:

FIG. 1 illustrates a system with a variable speed drive to both drive an electric motor and monitor motor winding degradation.

FIG. 2 illustrates a controller architecture for the variable speed drive.

FIG. 3 illustrates an exemplary graphical representation of positive and negative sequences generated by the controller and produced using a filtering module in real-time over a short time horizon.

FIG. 4 illustrates an exemplary graphical representation of positive and negative sequences produced using the filtering module at regularly spaced time intervals over a long time horizon.

FIG. 5 illustrates a scheme for processing measurements obtained from the drive to calculate one or more symmetric components and the frequency using an extended Kalman filter (EKF).

FIG. 6 illustrates a scheme for processing measurements obtained from the drive to calculate one or more symmetric components using a second-order generalized-integrator (SOGI) filter.

FIG. 7 illustrates a method for indicating the status of the motor winding using either a batch approach or real-time streaming approach.

FIG. 8 illustrates a method for classifying the status of the motor winding and generating actionable notifications.

### DEFINITIONS

A description of a few terms is necessary for ease of understanding the disclosed embodiments of the disclosed method and system elements.

The term “compressor” refers to a machine that draws low-pressure gas from auxiliary storage as raw input and then outputs high-pressure gas for storage or to feed other processes. The term “compressor” and “compressor elements” are not intended to be limiting in scope and may refer to positive displacement compressors and/or dynamic compressors (turbocompressors) and/or individual components of compressors.

The term “computer storage media” refers to physical storage media that store computer-executable instructions and/or data structures. Storage media, such as a digital data carrier, includes computer hardware, such as random access memory (RAM), read-only memory (ROM), electrically erasable programmable ROM (EEPROM), solid state drives (SSDs), flash memory, phase-change memory (PCM), optical disk storage, magnetic disk storage, and the like.

The term “controller” generally refers to a computerized command terminal comprising a collection of sensors and electrical components, i.e., to regulate various compressor elements. Compressor controllers include at least one main processing unit with a graphical interface and are adapted to monitor the instrumentation of various compressor parts (e.g., motors, rotors, filters, bearings, valves, pressure sensors, temperature sensors). A single controller may be arranged to monitor the instrumentation of multiple compressors. Exemplary compressor controllers operate to control safe startup and shutdown processes, provide real-time information of compressor instrumentation, adjust the power output of the motor(s), stabilize compressor operations, control process variables, alert and warn operators of issues, and/or initiate an automatic shutdown in case of unsafe conditions.

The term “network” refers to one or more data links that enable the wired or wireless transport of electronic data between computer systems and/or modules and/or other electronic devices.

The term “processor” or “processing unit” refers to one or more devices, circuits, and/or processing cores configured to process data, such as computer program instructions, and includes personal computers, computing units, desktop computers, laptop computers, message processors, hand-held devices, multi-processor systems, microprocessor-based or programmable consumer electronics, network PCs, minicomputers, mainframe computers, mobile telephones, PDAs, tablets, pagers, routers, switches, and the like. Unless otherwise stated, references to a first processor may also apply to a second processor and vice versa.

The term “service” refers to an automated program that performs different actions based on input. As used herein, the terms” executable module,” “executable component,” “component,” “module,” “service,” or “engine” can refer to hardware processing units or to software objects, routines, or methods that may be executed on with the dual component system and/or the software update system.

The term “software” generally refers to computer-executable instructions, code, data, applications, programs, program modules, or the like maintained in or on any form or type of computer-readable media that is configured for storing computer-executable instructions or the like in a manner that is accessible to a computing device.

The term “symmetric components” generally refers to a set of three components: (1) the zero-sequence (or homopolar) component, (2) the positive sequence (or direct) component, and (3) the negative sequence (or indirect) component.

The term “variable speed drive” (VSD) generally refers to a drive providing stepless variable control of the operating speed and/or torque of an electric motor. For clarity of presentation and without loss of generality, the term variable speed drive is used herein to refer to the class of drives including but not limited to an adjustable speed drive, an adjustable frequency drive, an adjustable frequency inverter, a variable frequency inverter, a variable frequency drive, and a converter unit.

As used herein, reference to any type of machine learning or artificial intelligence may include any type of machine learning algorithm or device, convolutional neural network(s), multilayer neural network(s), recursive neural network(s), recurrent neural network(s), deep neural network(s), decision tree model(s) (e.g., decision trees, random forests, and gradient boosted trees) linear regression model(s), logistic regression model(s), support vector machine(s) (SVM), artificial intelligence device(s), or any other type of intelligent computing system. Any amount of training data may be used (and perhaps later refined) to train the machine learning algorithm to perform the disclosed operations dynamically.

When introducing elements in the appended claims, the articles “a,” “an,” “the,” and “said” are intended to mean there are one or more of the elements. The terms “comprising,” “including,” and “having” are intended to be inclusive and mean that there may be additional elements other than the listed elements.

### DETAILED DESCRIPTION

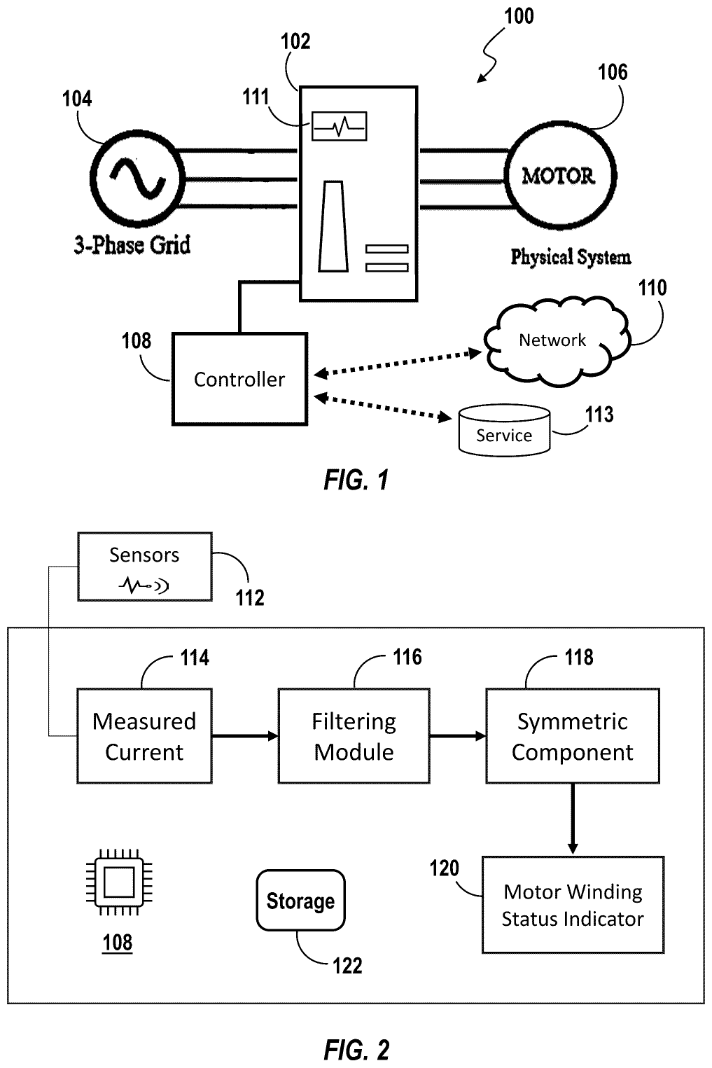

FIG. 1 illustrates an exemplary system 100 for monitoring motor winding degradation. The system includes a variable speed drive (VSD) 102 galvanically connected to an electrical supply grid 104 and an electric motor 106. The electrical supply grid 104 supplies electricity to the variable speed drive, which drives at least one electric motor 106. In a preferred embodiment, the electrical supply grid 104 is a 3-phase electrical supply grid. The electric motor 106 can drive a corresponding compressor, pump, or fan.

In an embodiment, the VSD 102 includes at least one rectifier, DC bus, and inverter unit. The inverter of the VSD 102 may be a current source inverter (CSI) or a voltage source inverter (VSI). The disclosed filtering techniques may be applied to the reference current (CSI) or voltage (VSI) and the resulting voltage or current. If a winding failure develops, a delta or deviation can be seen in measurements of at least the voltage, current, or both. In other words, the symmetric components can be computed for the three-phase current and/or the three-phase voltage. In calculating the symmetric components for the currents, the system uses the motor currents measured by sensors in the VSD 102. In calculating the symmetric components for the motor voltages, the system uses the instantaneous reference voltages calculated by the drive.

In an embodiment, the VSD 102 is arranged to match motor input requirements to fluctuations in demand output. The VSD 102 includes two or more sensors 112 to detect phase currents and/or phase voltages. In an embodiment, the VSD 102 includes a VSI and is part of a compressor system.

The VSD 102 is communicatively connected to a controller 108. The controller 108 generally comprises at least one processor and at least one hardware storage device (e.g., storage device 122) that stores computer-executable instructions by the processor to perform various tasks. In an embodiment, the controller 108 includes start/stop switches to initiate/deactivate procedures of running the connected electric motor 106. These procedures may be locally or remotely started and stopped. In an embodiment where the controller 108 is part of a compressor having an electric motor 106 for running a compressor element, the controller 108 includes the following characteristics: pressure regulation, monitoring and registering of running conditions, data retrieval (e.g., for monitoring service intervals and storing available data in “shut down” events), remote control and monitoring (e.g., digital) for centralized compressor management, relay monitoring. The controller 108 may be connected to a display 111 or graphical user interface to enable the following functions: displaying operating status, delivery air pressure, and drive motor rpm; reading out air delivery values; indicating compressor statuses of compressor loading, temperature, and pressure values; and the like. The display 111 may be a part of (i.e., physically connected to) the VSD 102 or part of a remotely connected computing unit (i.e., smartphone, tablet, computer). The controller 108 preferably enables app control (e.g., using Bluetooth® connection on a smartphone, tablet, or computer) and monitoring of the electric motor 106 via the VSD 102.

The interface of the controller 108 with the VSD 102 can be accessed via a connection to the network 110 in the embodiment where the controller 108 is integrated in the VSD 102. Thus, it is unnecessary to physically interact with the electric motor 106 or VSD 102 to operate the controller 108. In an embodiment where the controller 108 is part of the VSD 102, multiple electric motors 106, including those that do not have an integrated controller themselves, can use the controller 108 integrated with the VSD 102 via a network connection for controlling and monitoring the status of each electric motor 106.

The network 110 is communicatively coupled to the controller 108 of the VSD 102. The network 110 facilitates the transfer and distribution of information obtained from sensors 112 of the VSD 102 (see FIG. 2). In an alternative embodiment of the system 100, the controller 108 is connected to a service 113 instead of or in addition to the network 110. The service 113 may comprise components typical of a physical server, such as a motherboard, processor, memory storage device, one or more hard drives, a power supply, and a network adapter or external network connection capability. The service 113 may store one or more packages of software updates to the controller 108. In an embodiment, the service 113 is physically connected to the controller 108 to manually perform further processing of information obtained from sensors 112 of the VSD 102.

FIG. 2 illustrates general operations of the controller 108 for processing measured current and/or voltage values 114. The controller 108 is arranged to receive measured values 114 from two or more sensors 112 and/or to receive instantaneous values from two or more reference signals in the VSD 102 (e.g., in a voltage source inverter (VSI) the measured current values are “sensed” whereas the reference voltage values are “imposed”). Each measured or resulting (current and/or voltage) value 114 is processed through a filtering module 116 to compute one or more symmetric components 118. One skilled in the art will recognize that the value 114 can generally refer to multiple values measured simultaneously, i.e., a measured value 114 may be interpreted as part of a set of numerical values corresponding to the measured or resulting current and/or voltage. The filtering module 116 is generally a computing platform to update the estimated symmetric components 118 from the latest measured values 114. The controller 108 updates the resulting symmetric components 118 at each new incoming measured current and/or voltage value 114. In other words, based on immediately preceding measured values 114, the system 100 uses the mathematical model or filtering module 116 to update the symmetric components 118 instantaneously. In a preferred embodiment, the filtering module 116 updates the estimated symmetric components 118 for each measured or resulting (current and/or voltage) value 114 in real-time, i.e., between 100 and 1,000,000 samples of symmetric components 118 (preferably at least 1,000, and more preferably at least 5,000 samples) for the electric machine are calculated per second. In an embodiment, between 250 and 200,000 samples of symmetric components 118 of the electric machine comprising the electric motor 106 are calculated per second. The filtering module 116 includes an algorithm to calculate the symmetric components 118.

In an embodiment, the filtering module 116 comprises an extended Kalman filter (EKF) as a simplified, real-time streaming approach that recursively updates the symmetric components 118 using its input of measured values 114 at every sample occurrence. The EKF provides a simplified approach, compared to existing batch signal analysis methods (e.g., fast Fourier transform (FFT)), for calculating the symmetric components 118 to be used in monitoring insulation issues. The EKF allows the controller 108 to indicate the motor winding status 120 based on the calculated symmetric components 118. Using the EKF, the filtering module 116 provides at least 1,000, preferably at least 2,000, and more preferably at least 5,000 readings of symmetric components 118 per second, i.e., in real-time, which are used to assess trends of the positive sequence 126 and, more preferably, the negative sequence 128.

In an embodiment, the filtering module 116 comprises a second-order generalized-integrator (SOGI) filter as a real-time streaming approach that recursively updates the symmetric components 118 using its input of measured values 114. The SOGI filter provides a simplified approach, compared to existing batch signal analysis methods (e.g., FFT) and further provides better steady state results using a single input parameter. In an embodiment, the filtering module 116 includes additional input parameters to smooth over subsequent measured values 114 to produce smoothed traced features and reduce the impact of signal noise.

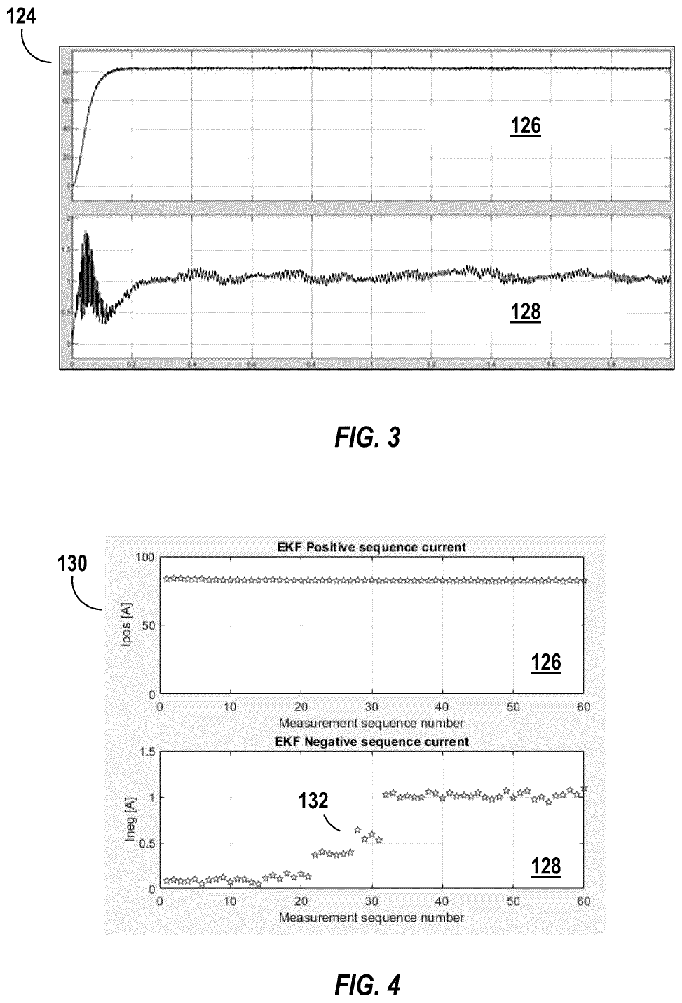

FIG. 3 illustrates a graphical representation 124 of a positive sequence 126 and a negative sequence 128 as the symmetric components 118 calculated in real-time. The graphical representation 124 may be produced in real-time as part of the motor winding status 120 indicator. The motor winding status 120 may be produced on a display of the VSD 102 or transferred to another service that has a display and is communicatively connected to network 110. Generating a motor winding status 120 (e.g., via graphical representation 124) in real-time indicates a general “health” state of the motor winding and can be used to alert users of needed maintenance or part replacement.

While FIG. 3 shows a real-time sequence of calculated symmetric components 118, FIG. 4 depicts one such calculated symmetric components 118 pair every second, minute, or day to illustrate the evolution of the symmetric components 118 when the winding becomes unbalanced due to a fault. FIG. 4 illustrates a graphical representation 130 of a series of calculated positive and negative sequences 126, 128 regularly spaced over a long time horizon (i.e., seconds, minutes, or days), wherein a fault reading 132 is observed with the negative sequence 128. The graphical representation 130 illustrates that the negative sequence 128 provides a fault reading 132 when the symmetry of a motor winding is corrupted. Such information is provided as part of the motor winding status 120. Other information, such as compressor statuses of compressor loading, temperature, and pressure values, can also be evaluated to some extent using the measured values 114 of the symmetric components 118. For example, when the positive sequence current is low, the loading of the compressor is low; however, proper evaluation of flow, pressure, and/or temperature levels based on the measured values 114 of the symmetric components 118 may require empirical formulas.

The collection of measurements of the symmetric components 118, particularly the negative sequence 128, over time, can provide an accurate motor winding status 120 for users to observe and determine whether or what action should be taken. For a particular type and model of a motor winding, a predetermined period may be defined as the reference time period. An initial sample or reference period could be, for example, determined when the electric motor 106 (i.e., with initial motor winding) is taken into service for the first time and may be based on the symmetric component 118 readings leading up to winding failure or deterioration. During the electric motor 106 operation, the symmetric components 118 gathered in a given time period may be regularly or even continuously compared with the symmetric components 118 from the reference time period to predict or anticipate possible motor winding degradation. When the estimated symmetric components 118 starts to deviate over time, the motor winding is degrading, and an actionable notification may be issued to a user for follow-up or investigation of the electric motor 106. Advantageously, providing updated calculations of the symmetric components 118 in real-time allows users to take immediate action to shut down and repair the electric motor 106 and corresponding motor windings. Furthermore, consequential damage could be avoided (e.g., when a motor winding burns and catches fire or performance loss occurs before effective failure).

The referenced symmetric components 118 and the estimated or real-time symmetric components 118 may further depend on parameters such as the operational pressure or other operating and motor conditions. In an embodiment, the motor winding status 120 is modeled, e.g., using a machine learning algorithm in a cloud environment or network 110, as the relation between the referenced symmetric components 118 and the motor condition by a polynomial, or another suitable type of fitted curve (e.g., a neural network regression), thereby generating a ground truth. During the operational life of the electric motor 106, the generated model could be updated based on the estimated and updated negative sequence 128 for each measured three-phase current. The difference between the updated model and the ground truth becomes larger and larger over time and establishes a reliable measure for calculating a level of motor winding degradation. When using the symmetric component analysis of both positive and negative sequences 126, 128, deviations can be identified within the controller 108 and/or within further processing means (e.g., cloud environment, network, service), and links or correlations between parameter deviations and fault types are thereby possible to obtain.

As noted above, the negative sequence 128 may be reported to a user using the motor winding status 120 indicator via controller 108. Furthermore, the data representative for the motor winding status 120 may be sent to another device for further processing. For example, the motor winding status 120 may be a value between zero and one, whereby zero corresponds to a failed motor winding, and one corresponds to a new and healthy motor winding. Alternatively, the health state may be reported as “healthy,” “degrading,” or “faulty.”

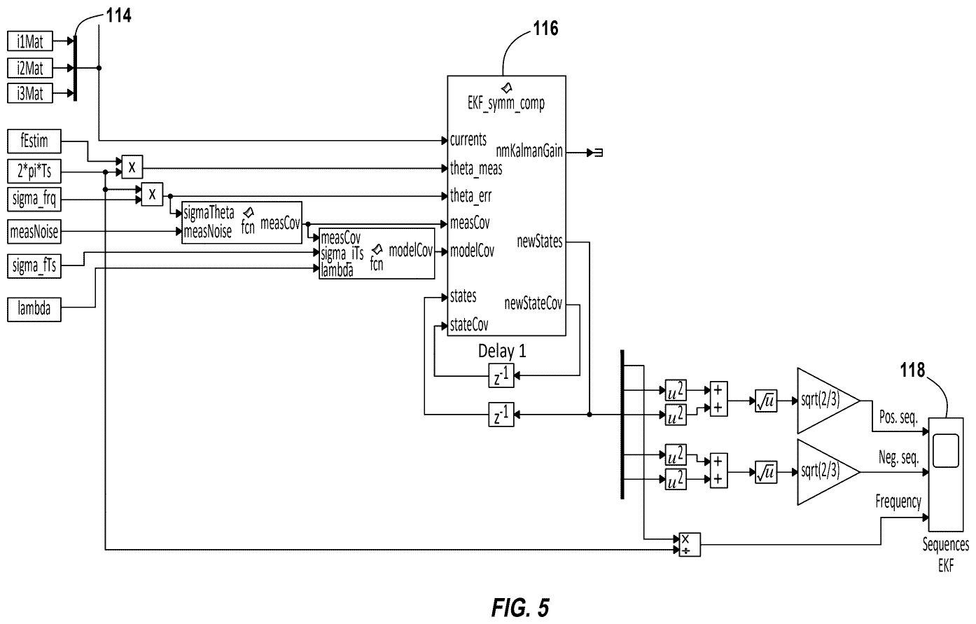

FIG. 5 illustrates a schematic diagram of how measured values 114 may be processed by the controller 108. The measured values 114 are obtained from a 3-phase power system and fed into a filtering module 116. In an embodiment, the filtering module 116 includes an extended Kalman filter algorithm to process the input values 114. The corresponding states or symmetric components 118 are then computed and output to a workspace. The present disclosure is not limited to the configuration of the extended Kalman filter and scheme as depicted, and one skilled in the art will recognize that alternative implementations of the filter may be utilized.

Regarding the schematic diagram in FIG. 5 illustrating an implementation of the EKF, the following elements and formulas are provided for exemplary purposes. The predicted (a priori) state estimate at iteration k for an embodiment of the EKF is defined as

$${\hat{x}}_{k \vert k - 1} = f ( {\hat{x}}_{k - 1 \vert k - 1} , {u}_{k - 1} )$$

The predicted (a priori) state estimate covariance is defined as

$${P}_{k \vert k - 1} = {F}_{k} {P}_{k - 1 \vert k - 1} {F}_{k}^{T} + {Q}_{k - 1}$$

The innovation is defined as

$${\tilde{y}}_{k} = {z}_{k} - h ( {\hat{x}}_{k \vert k - 1} )$$

The innovation covariance is defined as

$${S}_{k} = {H}_{k} {P}_{k \vert k - 1} {H}_{k}^{T} + {R}_{k}$$

The (near-optimal) Kalman gain is defined as

$${K}_{k} = {P}_{k \vert k - 1} {H}_{k}^{T} {S}_{k}^{- 1}$$

The updated (a posteriori) state estimate at iteration k is defined as

$${\hat{x}}_{k \vert k} = {\hat{x}}_{k \vert k - 1} + {K}_{k} {\tilde{y}}_{k}$$

The updated (a posteriori) state estimate covariance is defined as

$${P}_{k \vert k} = ( I - {K}_{k} {H}_{k} ) {P}_{k \vert k - 1}$$

Regarding FIG. 5, the following interpretations are made concerning the above: x refers to “states” or state estimate (a 5×1 vector); z refers to “currents” or measured/resulting current/voltage values (a 3×1 vector); P refers to “stateCov” or state estimate covariance (a 5×5 matrix); R refers to “measCov” or measurement covariance (a 3×3 matrix); and Q refers to “modelCov” or model covariance (a 5×5 matrix).

Additionally, the state estimate x is defined as

$$[ \begin{matrix}θ \\ {i}_{α}^{+} \\ {i}_{β}^{+} \\ {i}_{α}^{-} \\ {i}_{β}^{-}\end{matrix} ]$$

whereby theta is an angle representative for the dynamics of the current/voltage phasors, and whereby the remaining four quantities represent estimates for the positive (+) and negative (−) sequence components of the currents/voltages in the alpha (a)-beta (B) reference frame. These four quantities relate to their 3-phase counterpart (iₐ, i_{b}, i_{c}) via the following exemplary formulas:

$$M = \sqrt{\frac{2}{3}} [ \begin{matrix}1 & 0 \\ - \frac{1}{2} & \frac{\sqrt{3}}{2} \\ - \frac{1}{2} & - \frac{\sqrt{3}}{2}\end{matrix} ]$$

$$[ \begin{matrix}{i}_{α}^{+} \\ {i}_{β}^{+}\end{matrix} ] = {M}^{T} [ \begin{matrix}{i}_{a}^{+} \\ {i}_{b}^{+} \\ {i}_{c}^{+}\end{matrix} ]$$

$$[ \begin{matrix}{i}_{α} \\ {i}_{β}\end{matrix} ] = [ \begin{matrix}{i}_{α}^{+} & {i}_{α}^{-} \\ {i}_{β}^{+} & {i}_{β}^{-}\end{matrix} ] = {M}^{T} [ \begin{matrix}{i}_{a}^{+} & {i}_{a}^{-} \\ {i}_{b}^{+} & {i}_{b}^{-} \\ {i}_{c}^{+} & {i}_{c}^{-}\end{matrix} ] = {M}^{T} [ \begin{matrix}{i}_{a} \\ {i}_{b} \\ {i}_{c}\end{matrix} ]$$

The state covariance matrix P is iteratively updated, starting from the unity matrix at the very first iteration.

The measurement covariance R is defined as

$$R = [ \begin{matrix}{σ}_{f}^{2} & 0 & 0 \\ 0 & {σ}_{i}^{2} & 0 \\ 0 & 0 & {σ}_{i}^{2}\end{matrix} ]$$

whereby sigma_f (σ_{f}) and sigma_i (σᵢ) represent noise/error on the abovementioned phasor rotation speed and measured/resulting currents/voltages, respectively. These are typically known from the dynamic specifications of the application (sigma_f) and from the sensor specifications (sigma_i).

The model covariance Q is defined as

$$Q = [ \begin{matrix}{σ}_{f , {T}_{S}}^{2} & 0 & 0 & 0 & 0 \\ 0 & {λ}^{2} {σ}_{i}^{2} & 0 & 0 & 0 \\ 0 & 0 & {λ}^{2} {σ}_{i}^{2} & 0 & 0 \\ 0 & 0 & 0 & {λ}^{2} {σ}_{i}^{2} & 0 \\ 0 & 0 & 0 & 0 & {λ}^{2} {σ}_{i}^{2}\end{matrix} ]$$

whereby lambda (1) and sigma_f,Ts (σ_{f,T}_{_{S}}) are two independent smoothing factors to be determined upfront by the engineer. This smoothing is typical for Kalman filters and allows the engineer to weigh the importance of the model against the measurements.

Referring to the depicted embodiment, the EKF scheme includes some other matrices and functions, as clarified below. The matrix F is called the state transition matrix and is implemented as follows:

$$F = [ \begin{matrix}1 & 0 & 0 & 0 & 0 \\ 0 & cos θ & - sin θ & 0 & 0 \\ 0 & sin θ & cos θ & 0 & 0 \\ 0 & 0 & 0 & cos θ & sin θ \\ 0 & 0 & 0 & - sin θ & cos θ\end{matrix} ]$$

The function f is called the transition model and makes use of this transition matrix:

$$[ \begin{matrix}θ \\ {i}_{α}^{+} \\ {i}_{β}^{+} \\ {i}_{α}^{-} \\ {i}_{β}^{-}\end{matrix} ] ( k ) = [ \begin{matrix}1 & 0 & 0 & 0 & 0 \\ 0 & cos θ & - sin θ & 0 & 0 \\ 0 & sin θ & cos θ & 0 & 0 \\ 0 & 0 & 0 & cos θ & sin θ \\ 0 & 0 & 0 & - sin θ & cos θ\end{matrix} ] [ \begin{matrix}θ \\ {i}_{α}^{+} \\ {i}_{β}^{+} \\ {i}_{α}^{-} \\ {i}_{β}^{-}\end{matrix} ] ( k - 10$$

The matrix H is called the measurement or observation matrix and is implemented as follows:

$$H = [ \begin{matrix}1 & 0 & 0 & 0 & 0 \\ 0 & 1 & 0 & 1 & 0 \\ 0 & 0 & 1 & 0 & 1\end{matrix} ]$$

The function h is called the observation model and makes use of this observation matrix:

$$[ \begin{matrix}{θ}^{*} \\ {i}_{α}^{*} \\ {i}_{β}^{*}\end{matrix} ] ( k ) = [ \begin{matrix}1 & 0 & 0 & 0 & 0 \\ 0 & 1 & 0 & 1 & 0 \\ 0 & 0 & 1 & 0 & 1\end{matrix} ] [ \begin{matrix}θ \\ {i}_{α}^{+} \\ {i}_{β}^{+} \\ {i}_{α}^{-} \\ {i}_{β}^{-}\end{matrix} ] ( k )$$

The inventors also contemplate similar schemes and methods, and one skilled in the art will understand the underlying principles taught by the architecture observed in FIG. 5 and the above-noted formulas.

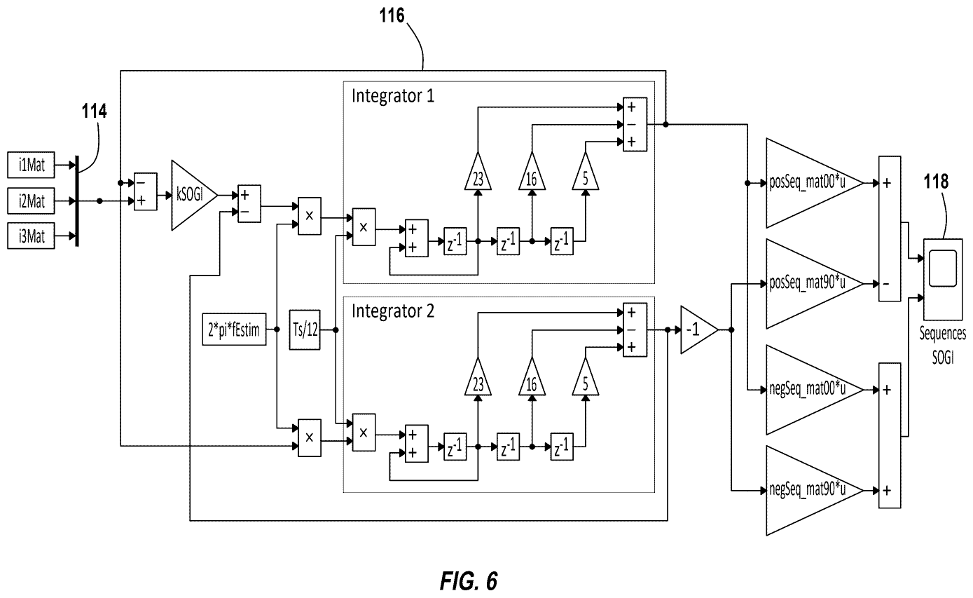

FIG. 6 illustrates a schematic diagram of an embodiment of the system using a second-order generalized-integrator (SOGI) filter to compute the symmetric components of a three-phase signal. The parameter kSOGI is set to be modifiable, which is typically set to a value close to 1. The SOGI filter system features two other parameters: the sample time Ts, which is fixed, and the estimated frequency of the signal fEstim. The latter is set to the frequency imposed by the variable speed drive. Such parameters may also be used in embodiments featuring an EKF model. The SOGI scheme is robust and allows slight deviations on fEstim compared to reality, so there is no risk of divergence with this scheme. The output of both integrators are two three-phase signals, which are shifted by 90° concerning each other. The outcome allows one to compute the sequences using the following matrix multiplications:

$$( \begin{matrix}{v}_{a}^{+} \\ {v}_{b}^{+} \\ {v}_{c}^{+}\end{matrix} ) = \frac{1}{3} ( \begin{matrix}1 & - \frac{1}{2} & - \frac{1}{2} \\ - \frac{1}{2} & 1 & - \frac{1}{2} \\ - \frac{1}{2} & - \frac{1}{2} & 1\end{matrix} ) ( \begin{matrix}{v}_{a} \\ {v}_{b} \\ {v}_{c}\end{matrix} ) - \frac{\sqrt{3}}{6} ( \begin{matrix}0 & - 1 & 1 \\ 1 & 0 & - 1 \\ - 1 & 1 & 0\end{matrix} ) ( \begin{matrix}{v}_{a}^{90} \\ {v}_{b}^{90} \\ {v}_{c}^{90}\end{matrix} )$$

$$( \begin{matrix}{v}_{a}^{-} \\ {v}_{b}^{-} \\ {v}_{c}^{-}\end{matrix} ) = \frac{1}{3} ( \begin{matrix}1 & - \frac{1}{2} & - \frac{1}{2} \\ - \frac{1}{2} & 1 & - \frac{1}{2} \\ - \frac{1}{2} & - \frac{1}{2} & 1\end{matrix} ) ( \begin{matrix}{v}_{a} \\ {v}_{b} \\ {v}_{c}\end{matrix} ) + \frac{\sqrt{3}}{6} ( \begin{matrix}0 & - 1 & 1 \\ 1 & 0 & - 1 \\ - 1 & 1 & 0\end{matrix} ) ( \begin{matrix}{v}_{a}^{90} \\ {v}_{b}^{90} \\ {v}_{c}^{90}\end{matrix} )$$

While the EKF updates the symmetric components by only using the last sample, the SOGI approach updates the symmetric components using the last three samples (e.g., see the three-delay block in FIG. 6, indicated by z-1). The number of samples used remains significantly smaller than what would be required for a conventional FFT method on a batch. Furthermore, the present disclosure is not limited to the configuration of the SOGI filter and scheme as depicted, and one skilled in the art will recognize that alternative implementations of the filter may be utilized.

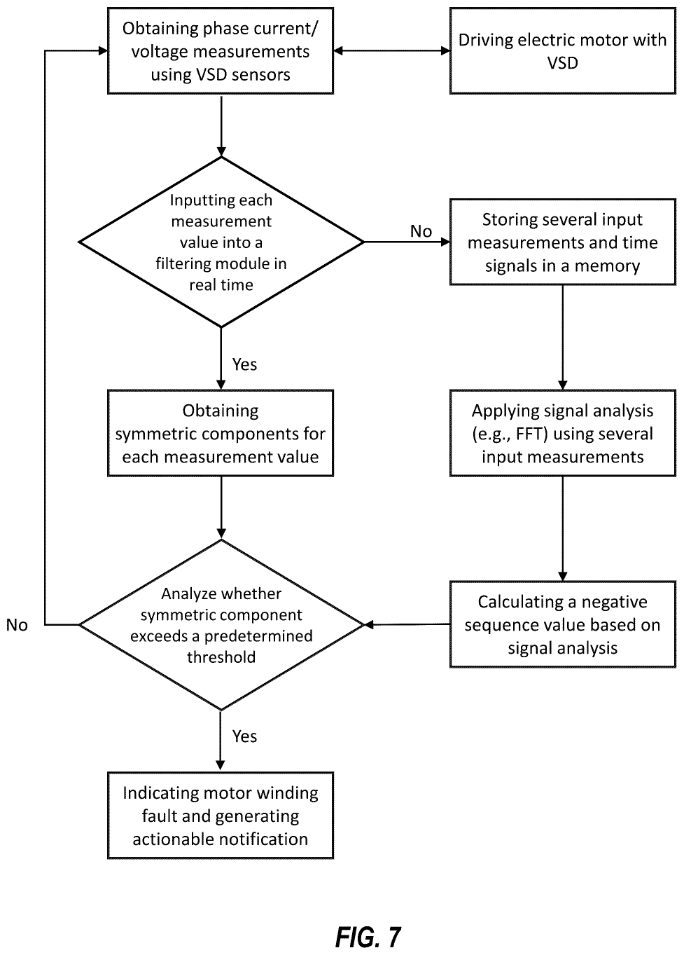

FIG. 7 illustrates an example of how the system 100 may monitor the status of a motor winding using either a batch approach or a real-time streaming approach. While simultaneously driving the electric motor, the inverter receives current measurements from a 3-phase power supply to the electric motor 106. In an embodiment, a batch of measured current values are stored in a memory or storage of a controller. The batch of measured current values may include a collection of data points gathered during a preset period, such as 200 milliseconds, 2 seconds, or 20 periods. The batch approach records currents and/or voltages for some time (e.g., 20 periods) before applying signal processing techniques to the entire data matrix, consequently causing noise on the measurements to have less impact on the overall estimated symmetric components. Given the operational speed and the number of pole-pairs of the motor, all signal vectors are filtered at the applied electrical frequency using an FFT algorithm (resulting in a set of phasors for currents and/or voltage), before applying the symmetric component Fortescue transformation (resulting in a positive, negative, and zero sequence for currents and/or voltage). Based on the calculated negative sequence value, the controller analyzes whether the symmetric component exceeds a predetermined threshold. If the threshold is exceeded, the controller indicates a motor winding fault and/or generates an actionable notification to the user—otherwise, the process restarts. In an embodiment, the process automatically restarts after indicating the motor winding fault or generating the actionable notification. In an alternative embodiment, the process further includes shutting down the electric motor.

FIG. 7 also depicts the controller bypassing the steps of storing a batch of measured current values to produce an entire data matrix before applying signal analysis. Instead, each measurement value is input into a filter model using a streaming or real-time approach. As noted above, the filter model can include an extended Kalman filter, a SOGI filter, or another similar filtering method. The filtering module calculates symmetric components for each measurement value, and the controller analyzes whether any sequence value of the symmetric components exceeds a predetermined threshold. If the threshold is exceeded, the controller indicates a motor winding fault and/or generates an actionable notification to the user. Otherwise, the process restarts. In an embodiment, the process automatically restarts after indicating the motor winding fault or generating the actionable notification. In an alternative embodiment, the process further includes shutting down the electric motor.

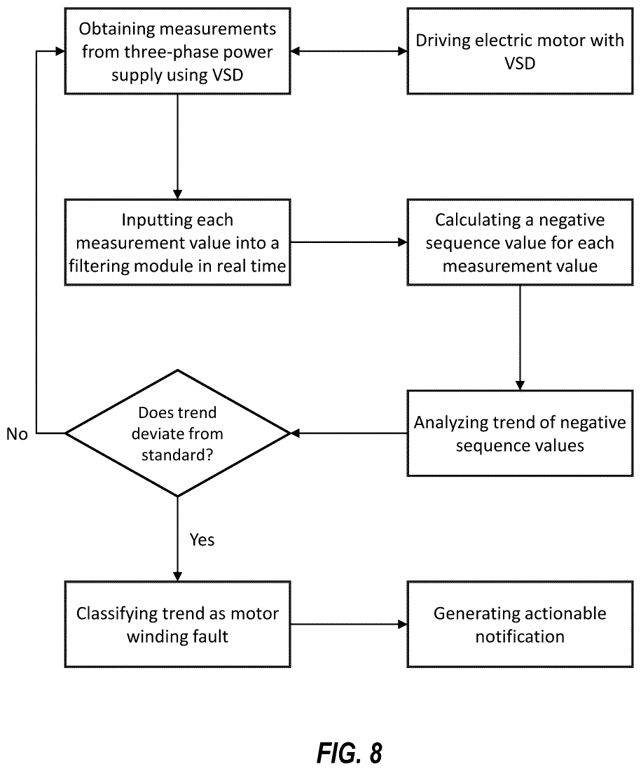

FIG. 8 illustrates a method for classifying a trend of symmetric components as a motor winding fault. While simultaneously driving the electric motor, the controller 108 receives current measurements from a 3-phase power supply to the electric motor 106. Each current measurement is input into a filter module in real-time. The filtering module calculates a negative sequence for each measurement value. In an embodiment, the controller 108 sends a trend of negative sequence values, i.e., collection of sequence values over an extended period of time (5 seconds, 5 minutes, etc.), to service (or network) for further processing. The service evaluates whether the trend deviates from a predetermined standard, including predefined values, limits, etc. If the trend does not deviate from a reference standard, the process restarts, and additional measurements are obtained and processed. If the trend is determined to have deviated from the reference standard, the service (or cloud environment in the network) uses a machine learning algorithm to classify the trend as relating to a type of motor winding fault. The type of motor winding fault may suggest cases of contaminants, abrasion, vibration, or partial discharges (i.e., the effect of voltage surges). The type of motor winding fault may also be broadly categorized as “degrading” or “faulty.” Based on the classified trend, the system can produce an actionable notification to alert the user of needed maintenance, replacement, or shutting down of an identified motor.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any combinations of one or more items listed in the associated list. It is further understood that relational terms such as first and second, and the like are used solely to distinguish one entity from another without necessarily requiring or implying any such relationship or order between such entities.

It is to be understood that even though numerous characteristics and advantages of various embodiments of the present disclosure have been outlined in the preceding description, together with details of the structure and function of various embodiments thereof, this detailed description is illustrative only, and changes may be made in detail, especially in matters of structure and arrangements of parts within the principles of the present disclosure to the full extent indicated by the broad general meaning of the terms in which the appended claims are expressed.

1. A method for monitoring motor winding degradation of an electric machine having an electric motor driven by a variable speed drive (VSD), the method comprising:
measuring phase current values directly from the VSD;
based on immediately preceding measured phase current values, updating symmetric components of the electric machine in real-time using a filtering module; and
producing a motor winding status based on the symmetric components;
wherein the VSD is used to both drive the electric motor and monitor the motor winding status.

2. The method of claim 1, wherein the symmetric components are calculated for each new incoming measurement of the phase current values.

3. The method of claim 1, further comprising bypassing storage of multiple subsequent phase current values in a memory to obtain a batch of current measurement samples and calculating the symmetric component of the electric machine in real-time.

4. The method of claim 1, wherein updating symmetric components of the electric machine is further based on an instantaneous set voltage imposed on the VSD.

5. The method of claim 1, wherein between 250 and 200,000 samples of symmetric components of the electric machine are calculated per second.

6. The method of claim 1, wherein the filter is an extended Kalman filter (EKF).

7. The method of claim 6, wherein the step of updating symmetric components of the electric machine in real-time, further includes providing a frequency estimator with the EKF.

8. The method of claim 1, wherein the filter includes a second-order generalized-integrator (SOGI) filter.

9. The method of claim 1, wherein the motor winding status indicates an insulation issue based on a deviation of the symmetric components from a balanced three-phase current system.

10. The method of claim 9 further comprising the step of providing a signal to the VSD in response to the indication of the insulation issue wherein the deviation exceeds a predetermined threshold value.

11. A system for monitoring motor winding degradation of an electric machine, the system comprising:
an electric motor;
an electrical supply grid; and
a variable speed drive (VSD) for driving the electric motor;
wherein the VSD is connected to a controller having one or more storage devices that store instructions that are executable to cause the controller to:
measure phase current values using at least two sensors of the VSD;
based on immediately preceding measured phase current values, update symmetric components of the electric machine in real-time using a filtering module; and
produce a motor winding status based on the symmetric components.

12. The system of claim 11, wherein the symmetric components are calculated for each new incoming measurement of the phase current values.

13. The system of claim 11, wherein the instructions are further executable to cause the controller to update symmetric components of the electric machine based on an instantaneous set voltage imposed on the VSD.

14. The system of claim 11, wherein between 250 and 200,000 samples of symmetric components of the electric machine are calculated per second.

15. The system of claim 11, wherein the filter is an extended Kalman filter (EKF).

16. The system of claim 11, wherein the filter includes a second-order generalized-integrator (SOGI) filter.

17. The system of claim 11, wherein the motor winding status indicates an insulation issue based on a deviation of the symmetric components from a balanced three-phase current system.

18. The system of claim 17, wherein the instructions are further executable by the controller to provide a signal to the VSD in response to the indication of the insulation issue wherein the deviation exceeds a predetermined threshold value.

19. The system of claim 11, wherein the VSD is galvanically connected to the electric motor and configured to automatically adjust operating speed in real-time.

20. A method for monitoring motor winding degradation of an electric machine having a variable speed drive (VSD) and electric motor, the method comprising:
measuring phase current values directly from the VSD;
based on immediately preceding measured phase current values, updating symmetric components of the electric machine in real-time using an extended Kalman filter (EKF) or second-order generalized-integrator (SOGI) filtering module;
wherein a new estimate of the symmetric components is generated at each new incoming measurement obtained using at least two sensors of the VSD.
